(19) United States
(12) Patent Application Publication
(10) Pub. No.: US 2025/0223479 A1
(43) Pub. Date: Jul. 10, 2025

(54) CMP SLURRY COMPOSITION FOR POLISHING TUNGSTEN AND METHOD FOR POLISHING TUNGSTEN USING THE SAME

(71) Applicant: SAMSUNG SDI CO., LTD., Yongin-si (KR)

(72) Inventors: Eui Rang LEE, Suwon-si (KR); Kun Bae NOH, Suwon-si (KR); Tae Won PARK, Suwon-si (KR); Ji Ho LEE, Suwon-si (KR); Byung Chang OH, Suwon-si (KR); Ji won BAEK, Suwon-si (KR); A Reum JUNG, Suwon-si (KR); Keun Sam JANG, Suwon-si (KR)

(21) Appl. No.: 19/006,342

(22) Filed: Dec. 31, 2024

(30) Foreign Application Priority Data
Jan. 5, 2024 (KR) 10-2024-0002027

(51) Int. Cl. C09K 3/14

(52) U.S. Cl. CPC C09K 3/1454

(57) ABSTRACT

A CMP slurry composition for polishing tungsten and a method of polishing tungsten using the composition, the composition includes a solvent, the solvent comprising a polar solvent or a nonpolar solvent; an abrasive agent; and a corrosion inhibitor, wherein the corrosion inhibitor includes a polyaminosilane having a weight average molecular weight of 500 g/mol to 5,000 g/mol, or a salt thereof.

### CROSS-REFERENCE TO RELATED APPLICATION

The present application claims priority and the benefit of Korean Patent Application No. 10-2024-0002027, filed on Jan. 5, 2024, in the Korean Intellectual Property Office, the entire disclosure of which is incorporated herein by reference.

### BACKGROUND

### 1. Field

Embodiments relate to a CMP slurry composition for polishing tungsten and a method for polishing tungsten using the same.

### 2. Description of the Related Art

Chemical mechanical polishing (CMP) compositions and methods for polishing (or planarizing) a surface of a substrate have been considered. Polishing compositions for polishing metal layers (such as tungsten) on a semiconductor substrate may include abrasive particles suspended in an aqueous solution and chemical accelerators such as oxidizing agents, catalysts, or the like.

A process of polishing a metal layer using a CMP composition may include the steps of polishing an initial metal layer, polishing the metal layer and a barrier layer, and polishing the metal layer, the barrier layer, and an oxide film.

### SUMMARY

The embodiments may be realized by providing a chemical mechanical polishing (CMP) slurry composition for polishing tungsten, the composition including a solvent, the solvent including a polar solvent or a nonpolar solvent; an abrasive agent; and a corrosion inhibitor, wherein the corrosion inhibitor includes a polyaminosilane having a weight average molecular weight of 500 g/mol to 5,000 g/mol, or a salt thereof.

The polyaminosilane may include a silicon-bonded hydroxyl group (*—Si—OH), a siloxane group (*—O—Si—O—*), or a free amino group.

The polyaminosilane may include a polymerized product of an aminosilane.

The aminosilane may include a compound represented by Formula 1:

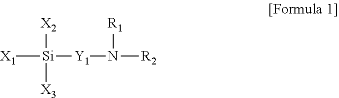

X₁, X₂, and X₃ may be each independently hydrogen, a hydroxyl group, a halogen, a substituted or unsubstituted C₁ to C₂₀ alkyl group, a substituted or unsubstituted C₆ to C₂₀ aryl group, a substituted or unsubstituted C₃ to C₂₀ cycloalkyl group, a substituted or unsubstituted C₇ to C₂₀ arylalkyl group, a substituted or unsubstituted C₁ to C₂₀ alkoxy group, or a substituted or unsubstituted C₆ to C₂₀ aryloxy group, at least one of X₁, X₂, and X₃ may be a hydroxyl group, a substituted or unsubstituted C₁ to C₂₀ alkoxy group, or a substituted or unsubstituted C₆ to C₂₀ aryloxy group, Y₁ may be a divalent aliphatic hydrocarbon group, a divalent cycloaliphatic hydrocarbon group, or a divalent aromatic hydrocarbon group, and R₁ and R₂ may be each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, a substituted or unsubstituted C₆ to C₃₀ monovalent aromatic group, a functional group represented by Formula 2, or a functional group represented by Formula 3:

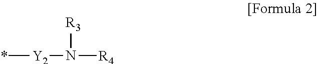

* is a linking site to nitrogen of Formula 1, Y₂ may be a divalent aliphatic hydrocarbon group, a divalent cycloaliphatic hydrocarbon group, or a divalent aromatic hydrocarbon group, and R₃ and R₄ may be each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group,

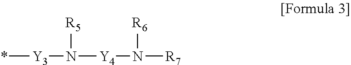

* is a linking site to nitrogen of Formula 1, Y₃ and Y₄ may be each independently a divalent aliphatic hydrocarbon group, a divalent cycloaliphatic hydrocarbon group, or a divalent aromatic hydrocarbon group, and R₅, R₆, and R₇ may be each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

The aminosilane may include aminopropyltriethoxysilane, aminopropyltrimethoxysilane, aminoethylaminopropyltrimethoxysilane, aminoethylaminopropyltriethoxysilane, aminoethylaminopropylmethyldimethoxysilane, aminoethylaminopropylmethyldiethoxysilane, aminoethylaminomethyltriethoxysilane, aminoethylaminomethylmethyldiethoxysilane, diethylenetriaminopropyltrimethoxysilane, diethylenetriaminopropyltriethoxysilane, diethylenetriaminopropylmethyldimethoxysilane, diethylenetriaminopropylmethyldiethoxysilane, or diethylenetriaminomethylmethyldiethoxysilane.

The polyaminosilane having a weight average molecular weight of 500 g/mol to 5,000 g/mol or the salt thereof may be present in an amount of 0.001 wt % to 10 wt %, based on a total weight of the CMP slurry composition.

The corrosion inhibitor may further include an additional corrosion inhibitor that is different from the polyaminosilane having a weight average molecular weight of 500 g/mol to 5,000 g/mol or the salt thereof.

The additional corrosion inhibitor may include an amino acid or an amine compound.

The abrasive agent may include a non-modified abrasive agent or a modified abrasive agent.

The abrasive agent may include the modified abrasive agent, and the modified abrasive agent may include silica modified with an aminosilane or a salt thereof.

The CMP slurry composition may further include an oxidizing agent, a catalyst, or an organic acid.

The CMP slurry composition may include, based on a total weight of the CMP slurry composition 0.001 wt % to 20 wt % of the abrasive agent, 0.001 wt % to 10 wt % of the corrosion inhibitor, 0.01 wt % to 20 wt % of the oxidizing agent, 0.001 wt % to 10 wt % of the catalyst, 0.001 wt % to 20 wt % of the organic acid, and the solvent.

The embodiments may be realized by providing a method of polishing tungsten, the method including polishing tungsten using the CMP slurry composition for polishing tungsten according to an embodiment.

The polyaminosilane may include a silicon-bonded hydroxyl group (*—Si—OH), a siloxane group (*—O—Si—O—*), or a free amino group.

The polyaminosilane may include a polymerized product of an aminosilane.

The aminosilane may include a compound represented by Formula 1:

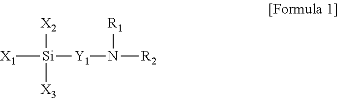

X₁, X₂, and X₃ may be each independently hydrogen, a hydroxyl group, a halogen, a substituted or unsubstituted C₁ to C₂₀ alkyl group, a substituted or unsubstituted C₆ to C₂₀ aryl group, a substituted or unsubstituted C₃ to C₂₀ cycloalkyl group, a substituted or unsubstituted C₇ to C₂₀ arylalkyl group, a substituted or unsubstituted C₁ to C₂₀ alkoxy group, or a substituted or unsubstituted C₆ to C₂₀ aryloxy group, at least one of X₁, X₂, and X₃ may be a hydroxyl group, a substituted or unsubstituted C₁ to C₂₀ alkoxy group, or a substituted or unsubstituted C₆ to C₂₀ aryloxy group, Y₁ may be a divalent aliphatic hydrocarbon group, a divalent cycloaliphatic hydrocarbon group, or a divalent aromatic hydrocarbon group, and R₁ and R₂ may be each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, a substituted or unsubstituted C₆ to C₃₀ monovalent aromatic group, a functional group represented by Formula 2, or a functional group represented by Formula 3:

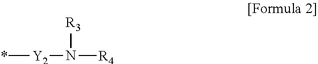

* is a linking site to nitrogen of Formula 1, Y₂ may be a divalent aliphatic hydrocarbon group, a divalent cycloaliphatic hydrocarbon group, or a divalent aromatic hydrocarbon group, and R₃ and R₄ may be each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group,

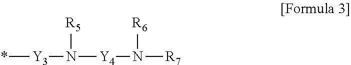

* is a linking site to nitrogen of Formula 1, Y₃ and Y₄ may be each independently a divalent aliphatic hydrocarbon group, a divalent cycloaliphatic hydrocarbon group, or a divalent aromatic hydrocarbon group, and R₅, R₆, and R₇ may be each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

The aminosilane may include aminopropyltriethoxysilane, aminopropyltrimethoxysilane, aminoethylaminopropyltrimethoxysilane, aminoethylaminopropyltriethoxysilane, aminoethylaminopropylmethyldimethoxysilane, aminoethylaminopropylmethyldiethoxysilane, aminoethylaminomethyltriethoxysilane, aminoethylaminomethylmethyldiethoxysilane, diethylenetriaminopropyltrimethoxysilane, diethylenetriaminopropyltriethoxysilane, diethylenetriaminopropylmethyldimethoxysilane, diethylenetriaminopropylmethyldiethoxysilane, or diethylenetriaminomethylmethyldiethoxysilane.

The corrosion inhibitor may further include an additional corrosion inhibitor that is different from the polyaminosilane having a weight average molecular weight of 500 g/mol to 5,000 g/mol or the salt thereof.

The composition may further include an oxidizing agent, a catalyst, or an organic acid.

The CMP slurry composition may include, based on a total weight of the CMP slurry composition 0.001 wt % to 20 wt % of the abrasive agent, 0.001 wt % to 10 wt % of the corrosion inhibitor, 0.01 wt % to 20 wt % of the oxidizing agent, 0.001 wt % to 10 wt % of the catalyst, 0.001 wt % to 20 wt % of the organic acid, and the solvent.

### DETAILED DESCRIPTION

It will be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B

Hereinafter, embodiments will be described in detail such that the embodiments can be implemented by those skilled in the art. It should be understood that the embodiments may be embodied in different ways and is not limited to the following embodiments.

The terminology used herein is for the purpose of describing exemplary embodiments and is not intended to limit the present application. As used herein, the singular forms “a”, “an”, and “the” are intended to include the plural forms as well, unless the context clearly indicates otherwise.

As used herein, “weight average molecular weight” may be obtained based on polystyrene conversion in gel permeation chromatography (GPC) or by referring to a product catalog. For example, weight average molecular weight may be determined under the following conditions:
Analyzer: HLC-8120GPC (Tosoh Chemical Co., Ltd.)
Column: G7000HXL+GMHXL+GMHXL (Tosoh Chemical Co., Ltd.)
Column size: 7.8 mmφ×30 cm each, totaling 90 cm
Column temperature: 40° C.
Flow rate: 0.8 ml/min
Injection volume: 100 μl
Eluent: Tetrahydrofuran
Detector: Differential refractometer (RI)
Reference sample: Polystyrene

As used herein, the term “substituted” in the expression “substituted or unsubstituted” means that at least one hydrogen atom in a corresponding functional group is substituted with one of a hydroxyl group, a halogen, a C₁ to C₂₀ alkyl group or haloalkyl group, a C₂ to C₁₀ alkenyl group or haloalkenyl group, a C₂ to C₁₀ alkynyl group or haloalkynyl group, a C₃ to C₁₀ cycloalkyl group, a C₃ to C₁₀ cycloalkenyl group, a C₆ to C₃₀ aryl group, a C₇ to C₃₀ arylalkyl group, a C₁ to C₁₀ alkoxy group, a C₆ to C₃₀ aryloxy group, an amino group, a cyano group, a nitro group, or a thiol group.

As used herein, a “monovalent organic group” may refer to a monovalent aliphatic hydrocarbon group, a monovalent cycloaliphatic hydrocarbon group, or a monovalent aromatic hydrocarbon group.

As used herein, a “monovalent aliphatic hydrocarbon group” may be a substituted or unsubstituted C₁ to C₂₀ linear or branched alkyl group, preferably a C₁ to C₁₀ alkyl group, more preferably a C₁ to C₅ alkyl group.

As used herein, a “monovalent cycloaliphatic hydrocarbon group” may be a substituted or unsubstituted C₃ to C₂₀ cycloalkyl group, preferably a C₃ to C₁₀ cycloalkyl group, more preferably a C₃ to C₅ cycloalkyl group.

As used herein, a “monovalent aromatic hydrocarbon group” may be a substituted or unsubstituted C₆ to C₃₀ aryl group or a substituted or unsubstituted C₇ to C₃₀ arylalkyl group, preferably a C₆ to C₁₀ aryl group or a C₇ to C₁₀ arylalkyl group.

As used herein, a “divalent aliphatic hydrocarbon group”, a “divalent cycloaliphatic hydrocarbon group”, or a “divalent aromatic hydrocarbon group” may be obtained by transforming the “monovalent aliphatic hydrocarbon group”, the “monovalent cycloaliphatic hydrocarbon group”, or the “monovalent aromatic hydrocarbon group” into a divalent form.

For example, the “divalent aliphatic hydrocarbon group” may be a substituted or unsubstituted C₁ to C₂₀ linear or branched alkylene group, preferably a C₁ to C₁₀ alkylene group, more preferably a C₁ to C₅ alkylene group; the “divalent cycloaliphatic hydrocarbon group” may be a substituted or unsubstituted C₃ to C₂₀ cycloalkylene group, preferably a C₃ to C₁₀ cycloalkylene group, more preferably a C₃ to C₅ cycloalkylene group; and the “divalent aromatic hydrocarbon group” may be a substituted or unsubstituted C₆ to C₃₀ arylene group or a substituted or unsubstituted C₇ to C₃₀ arylalkylene group, preferably a C₆ to C₁₀ arylene group or a C₇ to C₁₀ arylalkylene group.

As used herein to represent a specific numerical range, the expression “X to Y” means “greater than or equal to X and less than or equal to Y”.

In accordance with an embodiment, there may be provided a CMP slurry composition for polishing tungsten, which may polish tungsten at a high polishing rate, may reduce an etch rate of a patterned tungsten wafer, and may provide improved removal of irregularities on a surface of the patterned tungsten wafer.

The CMP slurry composition for polishing tungsten according to an embodiment (hereinafter referred to as a “CMP slurry composition”) may include, e.g., a solvent (including a polar solvent or a nonpolar solvent); an abrasive agent; and a corrosion inhibitor. In an implementation, the corrosion inhibitor may include, e.g., a polyaminosilane having a weight average molecular weight of 500 g/mol to 5,000 g/mol or a salt thereof.

In the following, each component of the CMP slurry composition will be described in detail.

### Corrosion Inhibitor

The CMP slurry composition may include a polyaminosilane having a weight average molecular weight of 500 g/mol to 5,000 g/mol (or a salt thereof) as the corrosion inhibitor.

The polyaminosilane may include a polymerized product of at least one aminosilane.

The aminosilane may include an aminoalkoxysilane or aminoaryloxysilane compound that has free amino groups along with an alkoxysilane group or an aryloxysilane group involved in polymerization.

The alkoxysilane group or the aryloxysilane group may facilitate preparation of a polyaminosilane having a weight average molecular weight in the above range by polymerizing the aminosilane. In an implementation, the alkoxysilane group or the aryloxysilane group may facilitate achievement of the desired effects of the CMP slurry composition described above by providing, e.g., a silicon-bonded hydroxyl group (*—Si—OH), or a siloxane group (*—O—Si—O—*) during polymerization.

Herein, “alkoxysilane group” refers to a functional group in which at least one alkoxy group is bonded to silicon, and does not necessarily refer to a functional group in which an alkoxy group is solely bonded to silicon. In an implementation, the alkoxysilane group may be a functional group in which an alkoxy group is solely bonded to silicone, or may be a functional group in which a functional group other than an alkoxy group is further bonded to silicon.

Herein, “aryloxysilane group” refers to a functional group in which at least one aryloxy group is bonded to silicon and does not necessarily refer to a functional group in which an aryloxy group is solely bonded to silicon. In an implementation, the aryloxysilane group may be a functional group in which an aryloxy group is solely bonded to silicon, or may be a functional group in which a functional group other than an aryloxy group is further bonded to silicon.

In an implementation, the amino groups may not be involved in polymerization, and at least some of the amino groups may be present in a free state in the polyaminosilane. The free amino groups may act as a corrosion inhibitor through adsorption onto tungsten, thereby aiding in reducing the etch rate of a patterned tungsten wafer, providing improved removal of step height on a surface of the patterned tungsten wafer, and preventing reduction in tungsten polishing rate. In an implementation, the amino groups may help stabilize the structure of the polyaminosilane by forming a hydrogen bond with each other or with a silicon-bonded hydroxyl group (*—Si—OH) in the polyaminosilane, thereby ensuring that the polyaminosilane in the CMP slurry composition provides intended effects thereof.

Herein, “amino group” may refer to a primary amine group (—NH₂), a secondary amine group (—NH—), or a tertiary amine group

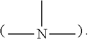

In an implementation, the polyaminosilane may have or include a silicon-bonded hydroxyl group (*—Si—OH), a siloxane group (*—O—Si—O—*), and a free amino group.

In an implementation, the aminosilane may be an aminosilane containing at least one nitrogen atom, e.g., 1 to 4 nitrogen atoms, or 1 to 3 nitrogen atoms. In an implementation, the aminosilane may include or be a compound represented by Formula 1:

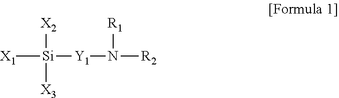

In Formula 1, X₁, X₂, and X₃ may each independently be or include, e.g., hydrogen, a hydroxyl group, a halogen, a substituted or unsubstituted C₁ to C₂₀ alkyl group, a substituted or unsubstituted C₆ to C₂₀ aryl group, a substituted or unsubstituted C₃ to C₂₀ cycloalkyl group, a substituted or unsubstituted C₇ to C₂₀ arylalkyl group, a substituted or unsubstituted C₁ to C₂₀ alkoxy group, or a substituted or unsubstituted C₆ to C₂₀ aryloxy group.

In an implementation, at least one of X₁, X₂, and X₃ may be, e.g., a hydroxyl group, a substituted or unsubstituted C₁ to C₂₀ alkoxy group, or a substituted or unsubstituted C₆ to C₂₀ aryloxy group.

Y₁ may be, e.g., a divalent aliphatic hydrocarbon group, a divalent cycloaliphatic hydrocarbon group, or a divalent aromatic hydrocarbon group.

R₁ and R₂ may each independently be or include, e.g., hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, a substituted or unsubstituted C₆ to C₃₀ monovalent aromatic group, a functional group represented by Formula 2, or a functional group represented by Formula 3.

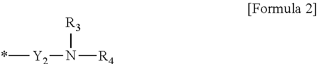

In Formula 2, * is a linking site to nitrogen (N) of Formula 1.

Y₂ may be, e.g., a divalent aliphatic hydrocarbon group, a divalent cycloaliphatic hydrocarbon group, or a divalent aromatic hydrocarbon group.

R₃ and R₄ may each independently be or include, e.g., hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

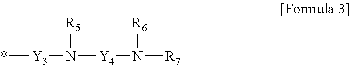

In Formula 3, * is a linking site to nitrogen (N) of Formula 1.

Y₃ and Y₄ may each independently be or include, e.g., a divalent aliphatic hydrocarbon group, a divalent cycloaliphatic hydrocarbon group, or a divalent aromatic hydrocarbon group.

R₅, R₆, and R₇ may each independently be or include, e.g., hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

In an implementation, X₁, X₂, and X₃ may each independently be, e.g., a hydroxyl group, a substituted or unsubstituted C₁ to C₂₀ alkyl group, or a substituted or unsubstituted C₁ to C₂₀ alkoxy group. In an implementation, at least one of X₁, X₂, and X₃ may be, e.g., a hydroxyl group or a substituted or unsubstituted C₁ to C₂₀ alkoxy group. In an implementation, in Formula 1, X₁, X₂, and X₃ may each independently be, e.g., a hydroxyl group or a substituted or unsubstituted C₁ to C₂₀ alkoxy group. The hydroxyl group and the substituted or unsubstituted C₁ to C₂₀ alkoxy group may facilitate acid- or base-catalyzed polymerization of the aminosilane.

In an implementation, Y₁ may be a divalent aliphatic hydrocarbon group, e.g. a substituted or unsubstituted C₁ to C₅ alkylene group.

In an implementation, R₁ and, R₂ may each be hydrogen. In an implementation, the compound represented by Formula 1 may be a silane containing an amino group (—NH₂) having one nitrogen atom. In an implementation, the compound represented by Formula 1 may be an aminopropyltrialkoxysilane, e.g., aminopropyltriethoxysilane (APTES) (3-aminopropyltriethoxysilane) or aminopropyltrimethoxysilane (3-aminopropyltrimethoxysilane).

In an implementation, R₁ may be hydrogen and R₂ may be a functional group represented by Formula 2. In an implementation, the compound represented by Formula 1 may be an aminosilane having two nitrogen atoms. In an implementation, Y₂ may be a divalent aliphatic hydrocarbon group, e.g., a substituted or unsubstituted C₁ to C₅ alkylene group. In an implementation, R₃ and R₄ may each be hydrogen, such that the compound represented by Formula 1 may be a silane containing an amino group (—NH₂) having two nitrogen atoms. In an implementation, the compound represented by Formula 1 may include, e.g., aminoethylaminopropyltrimethoxysilane, aminoethylaminopropyltriethoxysilane, aminoethylaminopropylmethyldimethoxysilane, aminoethylaminopropylmethyldiethoxysilane, aminoethylaminomethyltriethoxysilane, or aminoethylaminomethylmethyldiethoxysilane.

In an implementation, R₁ may be hydrogen and R₂ may be a functional group represented by Formula 3. In an implementation, the compound represented by Formula 1 may be an aminosilane having three nitrogen atoms. In an implementation, Y₃ and Y₄ may each independently be a divalent aliphatic hydrocarbon group, e.g. a substituted or unsubstituted C₁ to Cₛ alkylene group. In an implementation, R₆ and R₇ may each be hydrogen, such that the compound represented by Formula 1 may be a silane containing an amino group having three nitrogen atoms. In an implementation, the compound represented by Formula 1 may include, e.g., diethylenetriaminopropyltrimethoxysilane, diethylenetriaminopropyltriethoxysilane, diethylenetriaminopropylmethyldimethoxysilane, diethylenetriaminopropylmethyldiethoxysilane, or diethylenetriaminomethylmethyldiethoxysilane.

In an implementation, the aminosilane may be in a salt form and the polyaminosilane may be prepared by polymerization of the aminosilane in a salt form. In an implementation, a salt of the aminosilane may refer to a neutral salt composed of a cation and an anion derived from the compound represented by Formula 1.

The cation may be a quaternary ammonium cation derived from nitrogen of Formula 1. The anion may include: a halogen anion (e.g., F⁻, Cl⁻, Br⁻, I⁻); an organic acid anion, such as a carbonic acid anion (e.g., CO₃²⁻, HCO₃⁻), an acetic acid anion (CH₃COO⁻), or a citric acid anion (HOC(COO⁻) (CH₂COO⁻)₂); a nitrogen-containing anion (e.g., NO₃⁻, NO₂⁻): a phosphorus-containing anion (e.g., PO₄³⁻, HPO₄²⁻, H₂PO₄⁻); a sulfur-containing anion (e.g., SO₄²⁻, HSO₄⁻); and a cyanide anion (CN⁻).

The polyaminosilane may be prepared by polymerization of the aminosilane compounds described above. In an implementation, polymerization may be conducted in the presence of a catalyst including an acid catalyst or a base catalyst. The acid catalyst may be a strong acid, a weak acid, or the like, e.g., HCl, HNO₃, HCOOH, CH₃COOH, or HOC(═O)—C(═O) OH (oxalic acid). The base catalyst may be a strong base, a weak base, or the like, e.g., NaOH, KOH, or NH₄OH. Polymerization may be conducted at a temperature of 25° C. to 85° C., e.g., 40° C. to 70° C. Within these ranges, preparation of the polyaminosilane may be facilitated. Polymerization may be conducted in water or a water-miscible solvent (a mixture of water and an organic solvent). Polymerization may be conducted at a reaction pH in the acidic or basic range, e.g., in the range of 2 to 6, 3 to 5, 9 to 13, or 10 to 12. Within these ranges, preparation of the polyaminosilane may be facilitated.

The CMP slurry composition may include a polyaminosilane having a weight average molecular weight of 500 g/mol to 5,000 g/mol or a salt thereof. With the use of the polyaminosilane having a weight average molecular weight of 500 g/mol to 5,000 g/mol or the salt thereof instead of the (e.g., unpolymerized) aminosilane, the CMP slurry composition may polish tungsten at a high polishing rate, may reduce the etch rate of a patterned tungsten wafer, and may provide improved removal of irregularities on a surface of the patterned tungsten wafer.

Maintaining the weight average molecular weight of the polyaminosilane at 500 g/mol or greater may help ensure the effectiveness of the CMP slurry composition in reducing the etch rate of a patterned tungsten wafer and providing improved removal of step height on a surface of the tungsten wafer, since the effects obtained by addition of the polyaminosilane are small. Maintaining the weight average molecular weight of the polyaminosilane at 5,000 g/mol or less may help prevent a significant reduction in the effectiveness of the CMP slurry composition in polishing tungsten at a high polishing rate. In an implementation, the polyaminosilane or the salt thereof may have a weight average molecular weight of, e.g., 1,000 g/mol to 3,000 g/mol.

In an implementation, the polyaminosilane having a weight average molecular weight of 500 g/mol to 5,000 g/mol or the salt thereof may ensure that the CMP slurry composition polishes tungsten at a high polishing rate, reduces the etch rate of a patterned tungsten wafer, and provides improved removal of step height on a surface of the tungsten wafer upon polishing tungsten at a pH in the acidic or slightly acidic range. In an implementation, the CMP slurry composition may be adjusted to this molecular weight by adjusting one or more of the following conditions: reaction temperature, reaction pH, type or concentration of acid catalyst used, type or concentration of base catalyst used, or reaction time in preparation of the polyaminosilane by polymerization of the aminosilane.

The CMP slurry composition may be prepared by addition of the polyaminosilane having a weight average molecular weight of 500 g/mol to 5,000 g/mol or the salt thereof. Adding the aminosilane in preparation of the CMP slurry composition could make it difficult to prepare the polyaminosilane having a weight average molecular weight of 500 g/mol to 5,000 g/mol.

The polyaminosilane having a weight average molecular weight of 500 g/mol to 5,000 g/mol or the salt thereof may be present in an amount of 0.001 wt % to 10 wt %, e.g., 0.001 wt % to 1 wt %, based on a total weight of the CMP slurry composition. Within these ranges, it may be easy to ensure that the CMP slurry composition polishes tungsten at a high polishing rate, reduces the etch rate of a patterned tungsten wafer, and provides improved removal of irregularities on a surface of the patterned tungsten wafer.

In an implementation, the CMP slurry may include only the polyaminosilane having a weight average molecular weight of 500 g/mol to 5,000 g/mol or the salt thereof as the corrosion inhibitor. In an implementation, the polyaminosilane having a weight average molecular weight of 500 g/mol to 5,000 g/mol or the salt thereof may be present in an amount of 100 wt % based on the total weight of the corrosion inhibitor contained in the composition. Here, “corrosion inhibitor” may include a suitable material to reduce tungsten etch rates when used in a composition for polishing tungsten. In an implementation, the corrosion inhibitor may include an amino acid, an amine compound, or the like.

The amino acid may include, e.g., glycine, lysine, isoleucine, leucine, phenylalanine, methionine, threonine, tryptophan, valine, alanine, arginine, cysteine, glutamine, histidine, proline, serine, tyrosine, or lysine.

The amine compound may include, e.g., hexylamine, tetramethyl-p-phenylenediamine, octylamine, diethylenetriamine, dibutylbenzylamine, aminopropylsilanol, aminopropylsiloxane, dodecylamine, or a mixture thereof.

The amine compound may include a primary amine, a secondary amine, a tertiary amine, or a quaternary amine. The amine compound may further include a monoamine, a diamine, a triamine, a tetraamine, or an amine polymer having a large number of repeating amine groups (e.g., 4 or more amine groups).

The amine compound may include a long chain alkyl group. The long chain alkyl group refers to an alkyl group having 10 or more carbon atoms (e.g., 12 or more carbon atoms or 14 or more carbon atoms). The amine compound may include, e.g., dodecylamine, tetradecylamine, hexadecylamine, octadecylamine, oleylamine, N-methyldioctylamine, N-methyloctadecylamine, cocamidopropylamine oxide, benzyldimethylhexadecylammonium chloride, benzalkonium chloride, cocoalkylmethyl[polyoxyethylene (15)]ammonium chloride, octadecylmethyl[polyoxyethylene (15)]ammonium chloride, cetyltrimethylammonium bromide, or the like.

The amine compound may include a polycationic amine. The polycationic amine (as the term is used herein) is an amine compound having multiple (two or more) amine groups, wherein each of the amine groups is cationic (e.g., has a positive charge). In an implementation, the polycationic amine may include a polyquaternary amine. By polyquaternary amine, it is meant that the amine compound includes 2 to 4 quaternary ammonium groups such that the polyquaternary amine is a diquaternary amine compound, a triquaternary amine compound, or a tetraquaternary amine compound. The diquaternary amine compound may include, e.g., N,N′-methylenebis(dimethyltetradecylammonium bromide), 1,1,4,4-tetrabutylpiperazinediium dibromide, N,N,N′,N′,N′-pentamethyl-N-tallow-1,3-propane-diammonium dichloride, N,N′-hexamethylenebis(tributylammonium hydroxide), decamethonium bromide, didodecyl-tetramethyl-1,4-butanediaminium diiodide, 1,5-dimethyl-1,5-diazoniabicyclo(3.2.2) nonane dibromide, or the like. The triquaternary amine compound may include, e.g., N(1),N(6)-didoecyl-N(1),N(1),N(6),N(6)-tetramethyl-1,6-hexanediaminium diiodide. The tetraquaternary amine compound may include, e.g., methanetetrayltetrakis(tetramethylammonium bromide). The polyquaternary amine compound may further include a long chain alkyl group (e.g., having 10 or more carbon atoms). In an implementation, the polyquaternary amine compound having a long chain alkyl group may include N,N′-methylenebis(dimethyltetradecylammonium bromide), N,N,N′,N′,N′-pentamethyl-N-tallow-1,3-propane-diammonium dichloride, didodecyl-tetramethyl-1,4-butanediaminium diiodide, or N(1),N(6)-didodecyl-N (1),N(1),N(6),N(6)-tetramethyl-1,6-hexanediaminium diiodide.

In an implementation, the composition may further include an additional corrosion inhibitor, e.g., other than or different from the polyaminosilane having a weight average molecular weight of 500 g/mol to 5,000 g/mol or the salt thereof, as the corrosion inhibitor. For descriptive convenience, the polyaminosilane having a weight average molecular weight of 500 g/mol to 5,000 g/mol or the salt thereof will be referred to as a first corrosion inhibitor and the additional corrosion inhibitor, other than the polyaminosilane having a weight average molecular weight of 500 g/mol to 5,000 g/mol or the salt thereof, will be referred to as a second (or additional) corrosion inhibitor.

The second corrosion inhibitor may include an amino acid or an amine compound as described above. In an implementation, the second corrosion inhibitor may be an amino acid, e.g., glycine.

The second corrosion inhibitor may be present in an amount of 10 wt % or less, e.g., 0.01 wt % to 5 wt % or 0.02 wt % to 2 wt %, in the CMP slurry composition. Within these ranges, the second corrosion inhibitor may provide intended effects thereof without adversely affecting the desired effects of the polyaminosilane having a weight average molecular weight of 500 g/mol to 5,000 g/mol or the salt thereof.

The corrosion inhibitor may be present in an amount of 0.001 wt % to 10 wt %, e.g., 0.001 wt % to 1 wt % or 0.002 wt % to 0.2 wt %, in the CMP slurry composition. Within these ranges, it may be easy to ensure that the CMP slurry composition polishes tungsten at a high polishing rate, reduces the etch rate of a patterned tungsten wafer, and provides improved removal of irregularities on a surface of the patterned tungsten wafer.

### Solvent

The solvent (including a polar solvent or a non-polar solvent) may help reduce friction of the abrasive agent against a surface of a tungsten wafer upon polishing the tungsten wafer with the abrasive agent. The solvent may include water (e.g., ultrapure water or deionized water), organic amines, organic alcohols, organic alcohol amines, organic ethers, organic ketones, or the like. In an implementation, the solvent may include ultrapure water or deionized water. The solvent may be present in a balance amount, e.g., 30 wt % to 99 wt %, in the CMP slurry composition.

### Abrasive Agent

The abrasive agent may help polish an insulating film (e.g., a silicon oxide film) and tungsten at a high polishing rate.

The abrasive agent may be a metal or non-metal oxide and may include, e.g., silica, alumina, ceria, titania, or zirconia. In an implementation, the abrasive agent may include silica, which may facilitate achievement of the desired effects described herein.

The abrasive agent may be composed of spherical or non-spherical particles and may have an average primary particle diameter (D50) of 10 nm to 200 nm, e.g., 20 nm to 180 nm, or 30 nm to 150 nm. Within these ranges, the abrasive agent may help polish an insulating film and tungsten, which are polishing objects herein, at a high polishing rate while preventing defects (such as scratches) on a polished surface.

Herein, “average particle diameter (D50)” is a typical particle diameter measurement and refers to a particle diameter of the abrasive particles corresponding to 50 vol % when the abrasive particles are distributed in order from smallest to largest in terms of volume.

The abrasive agent may be present in an amount of 0.001 wt % to 20 wt %, e.g., 0.01 wt % to 10 wt %, 0.05 wt % to 5 wt %, or 0.1 wt % to 3 wt %, in the CMP slurry composition. Within these ranges, it is possible to ensure a sufficient polishing rate with respect to an insulating film and tungsten, prevention of scratches, and improved dispersion stability of silica.

The abrasive agent may include a non-modified abrasive agent or a modified abrasive agent.

In an implementation, the abrasive agent may be incorporated into the composition as the metal or non-metal oxide not subjected to modification.

In an implementation, the abrasive agent may be incorporated into the composition as the metal or non-metal oxide modified with at least one modifier. The modified abrasive agent may help significantly improve a polishing rate and flatness of a polished surface and may help reduce scratches, as compared to the non-modified abrasive agent. In an implementation, the modified abrasive agent may polish tungsten at a high polishing rate even at a pH in the slightly acidic range, which is higher than that of some other strongly acidic CMP slurry compositions.

In an implementation, the modified abrasive agent may include silica modified with an aminosilane.

The modified abrasive agent may have a positive charge on a surface thereof and may have a surface potential of 10 mV to 60 mV. Within this range, the modified abrasive agent may provide improvement in flatness of a polished surface and reduction in surface defects.

In an implementation, the modifier may include the aminosilane compounds described above or a salt thereof. The modified abrasive agent may be obtained by adding the modifier to a non-modified abrasive agent, followed by reaction for a predetermined period of time. In an implementation, the non-modified abrasive agent may include colloidal silica or fumed silica, e.g., colloidal silica.

In an implementation, the CMP slurry composition may further include, e.g., an oxidizing agent, a catalyst, or an organic acid.

The oxidizing agent may facilitate polishing of a tungsten wafer by oxidizing tungsten.

The oxidizing agent may include an inorganic per-compound, an organic per-compound, bromic acid or a salt thereof, nitric acid or a salt thereof, chloric acid or a salt thereof, chromic acid or a salt thereof, iodic acid or a salt thereof, iron or a salt thereof, copper or a salt thereof, a rare-earth metal oxide, a transition metal oxide, or potassium dichromate. Herein, “per-compound” refers to a compound containing at least one peroxide group (—O—O—) or containing an element in the highest oxidation state. In an implementation, the oxidizing agent may be a per-compound. In an implementation, the per-compound may include hydrogen peroxide, potassium periodate, calcium persulfate, or potassium ferricyanide, e.g., hydrogen peroxide. In an implementation, the oxidizing agent may be incorporated into the CMP slurry composition immediately prior to polishing.

The oxidizing agent may be present in an amount of 0.01 wt % to 20 wt %, e.g., 0.05 wt % to 10 wt %, or 0.1 wt % to 5 wt %, in the CMP slurry composition. Within these ranges, the CMP slurry composition may polish tungsten at an improved polishing rate.

The catalyst may include an iron ion compound, an iron ion complex, or a hydrate thereof.

An iron ion compound, an iron ion complex, or a hydrate thereof may help improve a polishing rate with respect to tungsten.

The iron ion compound may include a trivalent iron cation-containing compound. The trivalent iron cation-containing compound may include, e.g., a suitable compound in which trivalent iron cations are present as free cations in an aqueous solution thereof. In an implementation, the trivalent iron cation-containing compound may include, e.g., iron chloride (FeCl₃), iron nitrate (Fe(NO₃)₃), or iron sulfate (Fe₂(SO₄)₃).

The iron ion complex may include a trivalent iron cation-containing complex. The trivalent iron cation-containing complex may include a compound (or a salt thereof) formed by reacting trivalent iron cations in an aqueous solution thereof with an organic or inorganic compound having at least one functional group, e.g., carboxylic acids, phosphoric acids, sulfuric acids, amino acids, or amines. The organic or inorganic compound may include citrate, ammonium citrate, p-toluenesulfonic acid (pTSA), 1,3-propylenediaminetetraacetic acid (PDTA), ethylenediaminetetraacetic acid (EDTA), diethylenetriaminepentaacetic acid (DTPA), nitrilotriacetic acid (NTA), or ethylenediamine-N,N′-disuccinic acid (EDDS). The trivalent iron cation-containing complex may include, e.g., ferric citrate, ferric ammonium citrate, Fe(III)-pTSA, Fe(III)-PDTA, or Fe(III)-EDTA.

The catalyst, e.g., the iron ion compound, the iron ion complex, or the hydrate thereof, may be present in an amount of 0.001 wt % to 10 wt %, e.g., 0.001 wt % to 5 wt %, 0.001 wt % to 1 wt %, or 0.001 wt % to 0.5 wt %, in the CMP slurry composition. Within these ranges, the catalyst may help increase a polishing rate with respect to a tungsten film.

The organic acid may include a carboxylic acid, e.g., malonic acid, maleic acid, or malic acid.

The organic acid may be present in an amount of 0.001 wt % to 20 wt %, e.g., 0.01 wt % to 10 wt %, 0.01 wt % to 5 wt %, or 0.01 wt % to 1 wt %, in the CMP slurry composition. Within these ranges, the CMP slurry composition may help reduce both erosion and protrusion upon polishing tungsten.

The CMP slurry composition may have a pH of 2 to 6. With the use of the aforementioned non-modified silica or the modified silica as the abrasive agent, the CMP slurry composition according to an embodiment may achieve a high polishing rate with respect to tungsten even at a pH in the slightly acidic range, which is higher than that of a strongly acidic CMP slurry composition.

The CMP slurry composition may further include a pH regulator to adjust the pH of the composition to the above range.

In an implementation, the pH regulator may include: an inorganic acid, e.g., nitric acid, phosphoric acid, hydrochloric acid, or sulfuric acid; or an organic acid, e.g., an organic acid having a pKa of 6 or less, such as acetic acid or phthalic acid. In an implementation, the pH regulator may include a base, e.g., aqueous ammonia, sodium hydroxide, potassium hydroxide, ammonium hydroxide, sodium carbonate, or potassium carbonate.

In an implementation, in addition to the aforementioned components, the CMP slurry composition may further include a suitable additive, e.g., a biocide, a surfactant, a dispersant, a modifier, or a surface-active agent. The additive may be present in an amount of 0.001 wt % to 5 wt %, e.g., 0.001 wt % to 1 wt %, or 0.001 wt % to 0.5 wt %, in the CMP slurry composition. Within these ranges, the additive may help provide intended effects thereof without affecting a polishing rate.

In accordance with another embodiment, a method of polishing tungsten may include polishing tungsten using the CMP slurry composition for polishing tungsten according to the embodiments.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Details of components used in Examples and Comparative Examples were as follows:
(1) Non-modified abrasive agent: Colloidal silica having an average particle diameter (D₅₀) of 120 nm (PL-7, Fuso Chemical)
(2) pH regulator: nitric acid or aqueous ammonia

### Example 1

An aminosilane represented by Formula 4, in which Et is an ethyl group, was polymerized at a pH of 2.5 and a temperature of 65° C. for 8 hours, thereby obtaining a polymerized product of the aminosilane (weight average molecular weight: 1,500 g/mol).

Si(OEt)₃CH₂CH₂CH₂—NH₂ [Formula 4]

Based on a total weight of a final CMP slurry composition, 1.5 wt % of non-modified silica as an abrasive agent, 0.03 wt % of malonic acid as an organic acid, 0.15 wt % of glycine as a corrosion inhibitor, 0.001 wt % of ferric nitrate nonahydrate as an iron ion-containing compound, 0.001 wt % of diammonium salt of ethylenediaminetetraacetic acid, and 0.005 wt % of the obtained polymerized product of the aminosilane were mixed with deionized water, thereby preparing a composition. The resulting composition was adjusted to a pH of 2.5 using a pH regulator. Based on the total weight of a final CMP slurry composition, 0.5 wt % of hydrogen peroxide as an oxidizing agent was mixed with the resulting composition immediately prior to polishing, thereby preparing a CMP slurry composition for polishing tungsten, with the balance of deionized water.

### Example 2

A CMP slurry composition was prepared in the same manner as in Example 1 except that the content of the polymerized product of the aminosilane represented by Formula 4 was changed from 0.005 wt % to 0.01 wt %.

### Example 3

An aminosilane represented by Formula 5, in which Me is a methyl group, was polymerized at a pH of 2.5 and a temperature of 65° C. for 8 hours, thereby obtaining a polymerized product of the aminosilane (weight average molecular weight: 1,500 g/mol).

Si(OMe)₃CH₂CH₂CH₂—NH—CH₂CH₂—NH₂ [Formula 5]

Thereafter, a CMP slurry composition for polishing tungsten was prepared in the same manner as in Example 1 except that 0.005 wt % of the polymerized product of the aminosilane represented by Formula 5 was used instead of 0.005 wt % of the polymerized product of the aminosilane represented by Formula 4.

### Example 4

A CMP slurry composition was prepared in the same manner as in Example 3 except that the content of the polymerized product of the aminosilane represented by Formula 5 was changed from 0.005 wt % to 0.01 wt %.

### Example 5

An aminosilane represented by Formula 6, in which Me is a methyl group, was polymerized at a pH of 2.5 and a temperature of 65° C. for 8 hours, thereby obtaining a polymerized product of the aminosilane (weight average molecular weight: 1,500 g/mol).

Si(OMe)₃CH₂CH₂CH₂—NH—CH₂CH₂—NH—CH₂CH₂—NH₂ [Formula 6]

Thereafter, a CMP slurry composition for polishing tungsten was prepared in the same manner as in Example 1 except that 0.005 wt % of the polymerized product of the aminosilane represented Formula 6 was used instead of 0.005 wt % of the polymerized product of the aminosilane represented by Formula 4.

### Example 6

A CMP slurry composition was prepared in the same manner as in Example 5 except that the content of the polymerized product of the aminosilane represented by Formula 6 was changed from 0.005 wt % to 0.01 wt %.

### Comparative Example 1

A CMP slurry composition was prepared in the same manner as in Example 1 except that the polymerized product of the aminosilane represented by Formula 4 was not used.

### Comparative Example 2

A CMP slurry composition was prepared in the same manner as in Example 1 except that 0.01 wt % of the (unpolymerized) aminosilane represented by Formula 4 was used instead of the polymerized product of the aminosilane represented by Formula 4.

### Comparative Example 3

A CMP slurry composition was prepared in the same manner as in Example 1 except that the polymerization conditions of the aminosilane represented by Formula 4 were changed to provide a polymerized product of the aminosilane having a weight average molecular weight of 350 g/mol and the polymerized product was present in an amount of 0.01 wt %.

### Comparative Example 4

A CMP slurry composition was prepared in the same manner as in Example 1 except that the polymerization conditions of the aminosilane represented by Formula 4 were changed to provide a polymerized product of the aminosilane having a weight average molecular weight of 5,500 g/mol and the polymerized product was present in an amount of 0.01 wt %.

Each of the CMP slurry compositions prepared in Examples 1 to 6 and Comparative Examples 1 to 4 was evaluated as to polishing characteristics under the following polishing evaluation conditions. Results are shown in Table 1.

### [Polishing Evaluation Conditions]

1. Polishing machine: Reflexion LK 300 mm (AMAT Co., Ltd.)
2. Polishing conditions
   Polishing pad: IC1010 (DuPont Inc.)
   Head speed: 101 rpm
   Platen speed: 100 rpm
   Polishing pressure: 2 psi
   Retainer ring pressure: 9 psi
   Slurry flow rate: 240 ml/min
   Polishing time: 60 seconds
3. Polishing object
   A Commercially available patterned tungsten wafer (MIT 854, 300 mm)

A CMP slurry for polishing tungsten (STARPLANAR-7000, Samsung SDI Co., Ltd.) was mixed with deionized water in a weight ratio of 1:2, followed by addition of 2 wt % of hydrogen peroxide based on the total weight of the mixture, and then, using the resulting mixture, the patterned tungsten wafer was primarily polished on a polishing machine (Reflexion LK 300 mm) with a polishing pad (IC1010, DuPont Inc.) under conditions of: a head speed of 101 rpm; a platen speed of 100 rpm, a polishing pressure of 2 psi, a retainer ring pressure of 9 psi, and a mixture flow rate of 250 ml/min. Through this process, a tungsten metal layer was removed such that an oxide film/metal pattern was exposed.
4. Analysis method

Polishing rate (unit: Å/min): After polishing the patterned tungsten wafer under the above polishing conditions, an oxide film polishing rate was obtained by conversion of a difference in film thickness before and after polishing using a reflectometer and a tungsten polishing rate was obtained by conversion of a difference in resistance before and after polishing.

Erosion (unit: nm): After polishing the patterned tungsten wafer under the above polishing conditions, the profile of the wafer pattern was measured using an atomic force profiler (InSight CAP, Bruker Co., Ltd.). Erosion was calculated based on a height difference between a peri oxide film and a cell oxide film in a 0.18 μm×0.18 μm patterned area of the polished wafer. Here, a scanning rate was set to 100 μm/sec and a scanning length was set to 2 mm.

Etch rate (unit: Å/min): A non-patterned tungsten wafer was cut to a size of 2 cm×2 cm, followed by dipping in the slurry at 60° C. for 5 minutes. The etch rate of the tungsten wafer was obtained through comparison between etched amounts before and after dipping in the slurry.

TABLE 1

| | Example | | | | | | Comparative Example | | | |
|---|---|---|---|---|---|---|---|---|---|---|
| | 1 | 2 | 3 | 4 | 5 | 6 | 1 | 2 | 3 | 4 |
| Tungsten | 165 | 157 | 155 | 136 | 149 | 130 | 180 | Particle | 172 | 116 |
| polishing rate | | | | | | | | aggregation | | |
| (Å/min) | | | | | | | | | | |
| Oxide film | 479 | 482 | 485 | 481 | 491 | 461 | 490 | | 487 | 451 |
| polishing rate | | | | | | | | | | |
| (Å/min) | | | | | | | | | | |
| Erosion (nm) | 17.2 | 14.9 | 13.2 | 11.7 | 14 | 12.5 | 20.7 | | 20.2 | 28.2 |
| Etch rate | 52 | 36 | 44 | 25 | 44 | 22 | 168 | | 69 | 21 |
| (Å/min) | | | | | | | | | | |

As may be seen from Table 1, the CMP slurry compositions of Examples 1 to 6 polished tungsten at a high polishing rate, reduced the etch rate of a patterned tungsten wafer, and provided improved removal of irregularities on a surface of the tungsten wafer.

Conversely, the compositions of Comparative Examples 1 to 4, free from the polyaminosilane having a weight average molecular weight of 500 g/mol to 5,000 g/mol, failed to provide all of the desired effects described above.

One or more embodiments may provide a CMP slurry composition for polishing tungsten, which may polish tungsten at a high polishing rate, may reduce an etch rate of a patterned tungsten wafer, and may provide improved removal of step height on a surface of the patterned tungsten wafer.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A chemical mechanical polishing (CMP) slurry composition for polishing tungsten, the composition comprising:
a solvent, the solvent comprising a polar solvent or a nonpolar solvent;
an abrasive agent; and
a corrosion inhibitor,
wherein the corrosion inhibitor comprises:
a polyaminosilane having a weight average molecular weight of 500 g/mol to 5,000 g/mol, or
a salt thereof.

2. The CMP slurry composition as claimed in claim 1, wherein the polyaminosilane comprises a silicon-bonded hydroxyl group (*—Si—OH), a siloxane group (*—O—Si—O—*), or a free amino group.

3. The CMP slurry composition as claimed in claim 1, wherein the polyaminosilane comprises a polymerized product of an aminosilane.

4. The CMP slurry composition as claimed in claim 3, wherein:
the aminosilane comprises a compound represented by Formula 1: 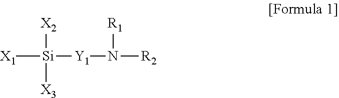
X₁, X₂, and X₃ are each independently hydrogen, a hydroxyl group, a halogen, a substituted or unsubstituted C₁ to C₂₀ alkyl group, a substituted or unsubstituted C₆ to C₂₀ aryl group, a substituted or unsubstituted C₃ to C₂₀ cycloalkyl group, a substituted or unsubstituted C₇ to C₂₀ arylalkyl group, a substituted or unsubstituted C₁ to C₂₀ alkoxy group, or a substituted or unsubstituted C₆ to C₂₀ aryloxy group,
at least one of X₁, X₂, and X₃ is a hydroxyl group, a substituted or unsubstituted C₁ to C₂₀ alkoxy group, or a substituted or unsubstituted C₆ to C₂₀ aryloxy group,
Y₁ is a divalent aliphatic hydrocarbon group, a divalent cycloaliphatic hydrocarbon group, or a divalent aromatic hydrocarbon group, and
R₁ and R₂ are each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, a substituted or unsubstituted C₆ to C₃₀ monovalent aromatic group, a functional group represented by Formula 2, or a functional group represented by Formula 3: 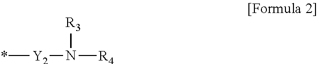
* is a linking site to nitrogen of Formula 1,
Y₂ is a divalent aliphatic hydrocarbon group, a divalent cycloaliphatic hydrocarbon group, or a divalent aromatic hydrocarbon group, and
R₃ and R₄ are each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group, 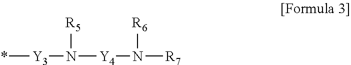
* is a linking site to nitrogen of Formula 1,
Y₃ and Y₄ are each independently a divalent aliphatic hydrocarbon group, a divalent cycloaliphatic hydrocarbon group, or a divalent aromatic hydrocarbon group, and
R₅, R₆, and R₇ are each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

5. The CMP slurry composition as claimed in claim 3, wherein the aminosilane comprises aminopropyltriethoxysilane, aminopropyltrimethoxysilane, aminoethylaminopropyltrimethoxysilane, aminoethylaminopropyltriethoxysilane, aminoethylaminopropylmethyldimethoxysilane, aminoethylaminopropylmethyldiethoxysilane, aminoethylaminomethyltriethoxysilane, aminoethylaminomethylmethyldiethoxysilane, diethylenetriaminopropyltrimethoxysilane, diethylenetriaminopropyltriethoxysilane, diethylenetriaminopropylmethyldimethoxysilane, diethylenetriaminopropylmethyldiethoxysilane, or diethylenetriaminomethylmethyldiethoxysilane.

6. The CMP slurry composition as claimed in claim 1, wherein the polyaminosilane having a weight average molecular weight of 500 g/mol to 5,000 g/mol or the salt thereof is present in an amount of 0.001 wt % to 10 wt %, based on a total weight of the CMP slurry composition.

7. The CMP slurry composition as claimed in claim 1, wherein the corrosion inhibitor further comprises an additional corrosion inhibitor that is different from the polyaminosilane having a weight average molecular weight of 500 g/mol to 5,000 g/mol or the salt thereof.

8. The CMP slurry composition as claimed in claim 7, wherein the additional corrosion inhibitor comprises an amino acid or an amine compound.

9. The CMP slurry composition as claimed in claim 1, wherein the abrasive agent comprises a non-modified abrasive agent or a modified abrasive agent.

10. The CMP slurry composition as claimed in claim 9, wherein:
the abrasive agent comprises the modified abrasive agent, and
the modified abrasive agent comprises silica modified with an aminosilane or a salt thereof.

11. The CMP slurry composition as claimed in claim 1, further comprising an oxidizing agent, a catalyst, or an organic acid.

12. The CMP slurry composition as claimed in claim 11, wherein the CMP slurry composition comprises, based on a total weight of the CMP slurry composition:
0.001 wt % to 20 wt % of the abrasive agent,
0.001 wt % to 10 wt % of the corrosion inhibitor,
0.01 wt % to 20 wt % of the oxidizing agent,
0.001 wt % to 10 wt % of the catalyst,
0.001 wt % to 20 wt % of the organic acid, and
the solvent.

13. A method of polishing tungsten, the method comprising:
polishing tungsten using the CMP slurry composition for polishing tungsten as claimed in claim 1.

14. The method as claimed in claim 13, wherein the polyaminosilane comprises a silicon-bonded hydroxyl group (*—Si—OH), a siloxane group (*—O—Si—O—*), or a free amino group.

15. The method as claimed in claim 13, wherein the polyaminosilane comprises a polymerized product of an aminosilane.

16. The method as claimed in claim 15, wherein:
the aminosilane comprises a compound represented by Formula 1: 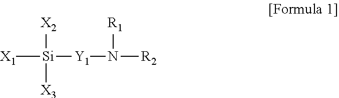
X₁, X₂, and X₃ are each independently hydrogen, a hydroxyl group, a halogen, a substituted or unsubstituted C₁ to C₂₀ alkyl group, a substituted or unsubstituted C₆ to C₂₀ aryl group, a substituted or unsubstituted C₃ to C₂₀ cycloalkyl group, a substituted or unsubstituted C₇ to C₂₀ arylalkyl group, a substituted or unsubstituted C₁ to C₂₀ alkoxy group, or a substituted or unsubstituted C₆ to C₂₀ aryloxy group,
at least one of X₁, X₂, and X₃ is a hydroxyl group, a substituted or unsubstituted C₁ to C₂₀ alkoxy group, or a substituted or unsubstituted C₆ to C₂₀ aryloxy group,
Y₁ is a divalent aliphatic hydrocarbon group, a divalent cycloaliphatic hydrocarbon group, or a divalent aromatic hydrocarbon group, and
R₁ and R₂ are each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, a substituted or unsubstituted C₆ to C₃₀ monovalent aromatic group, a functional group represented by Formula 2, or a functional group represented by Formula 3: 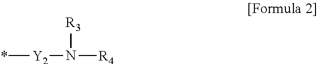
* is a linking site to nitrogen of Formula 1,
Y₂ is a divalent aliphatic hydrocarbon group, a divalent cycloaliphatic hydrocarbon group, or a divalent aromatic hydrocarbon group, and
R₃ and R₄ are each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group, 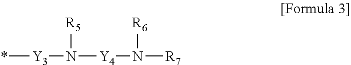
* is a linking site to nitrogen of Formula 1,
Y₃ and Y₄ are each independently a divalent aliphatic hydrocarbon group, a divalent cycloaliphatic hydrocarbon group, or a divalent aromatic hydrocarbon group, and
R₅, R₆, and R₇ are each independently hydrogen, a hydroxyl group, a substituted or unsubstituted C₁ to C₂₀ monovalent aliphatic hydrocarbon group, a substituted or unsubstituted C₃ to C₂₀ monovalent cycloaliphatic hydrocarbon group, or a substituted or unsubstituted C₆ to C₃₀ monovalent aromatic hydrocarbon group.

17. The method as claimed in claim 15, wherein the aminosilane comprises aminopropyltriethoxysilane, aminopropyltrimethoxysilane, aminoethylaminopropyltrimethoxysilane, aminoethylaminopropyltriethoxysilane, aminoethylaminopropylmethyldimethoxysilane, aminoethylaminopropylmethyldiethoxysilane, aminoethylaminomethyltriethoxysilane, aminoethylaminomethylmethyldiethoxysilane, diethylenetriaminopropyltrimethoxysilane, diethylenetriaminopropyltriethoxysilane, diethylenetriaminopropylmethyldimethoxysilane, diethylenetriaminopropylmethyldiethoxysilane, or diethylenetriaminomethylmethyldiethoxysilane.

18. The method as claimed in claim 13, wherein, wherein the corrosion inhibitor further comprises an additional corrosion inhibitor that is different from the polyaminosilane having a weight average molecular weight of 500 g/mol to 5,000 g/mol or the salt thereof.

19. The method as claimed in claim 13, wherein the composition further comprises an oxidizing agent, a catalyst, or an organic acid.

20. The method as claimed in claim 19, wherein the CMP slurry composition comprises, based on a total weight of the CMP slurry composition:
0.001 wt % to 20 wt % of the abrasive agent,
0.001 wt % to 10 wt % of the corrosion inhibitor,
0.01 wt % to 20 wt % of the oxidizing agent,
0.001 wt % to 10 wt % of the catalyst,
0.001 wt % to 20 wt % of the organic acid, and
the solvent.
